(19) United States
(12) Patent Application Publication
(10) Pub. No.: US 2014/0143511 A1
(43) Pub. Date: May 22, 2014

(54) INTERFACE CONVERSION DEVICE AND STORAGE DEVICE USING THE SAME

(71) Applicants: INVENTEC (PUDONG) TECHNOLOGY CORPORATION, Shanghai (CN); INVENTEC CORPORATION, Taipei City (TW)

(72) Inventors: Ying-Fan Chiang, Taipei City (TW); Chun-Hao Chu, Taipei City (TW); Chun-Yuan Chen, Taipei City (TW)

(73) Assignees: INVENTEC CORPORATION, Taipei City (TW); INVENTEC (PUDONG) TECHNOLOGY CORPORATION, Shanghai (CN)

(21) Appl. No.: 13/846,288

(22) Filed: Mar. 18, 2013

(30) Foreign Application Priority Data
Nov. 16, 2012 (CN) 201210464611.2

(51) Int. Cl. G11C 7/10

(52) U.S. Cl. CPC G11C 7/1075
USPC 711/149

(57) ABSTRACT

An interface conversion device, applicable to a storage device, includes a first connection port, a second connection port, a measuring unit and a processing unit. The first connection port transmits a first signal and a power signal via a first communication interface. The second connection port transmits a second signal and the power signal to the storage device via a second communication interface. The first communication interface and the second communication interface are different from each other. The measuring unit receives the power signal from the first connection port to measure the power signal and produce a measurement signal. The measuring unit outputs the power signal to the second connection port. The processing unit receives and converts the first signal into the second signal and outputs the second signal via the second connection port. The processing unit receives the measurement signal to calculate a power consumption value.

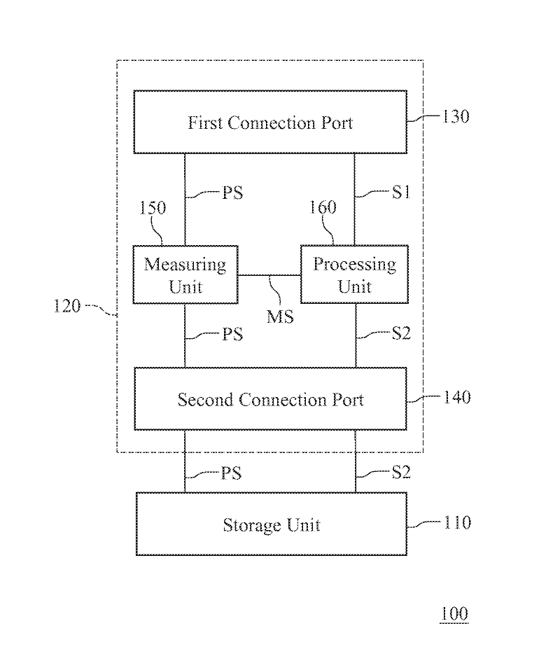

### CROSS-REFERENCE TO RELATED APPLICATIONS

This non-provisional application claims priority under 35 U.S.C. §119(a) on Patent Application No(s). 201210464611.2 filed in China on Nov. 16, 2012, the entire contents of which are hereby incorporated by reference.

### BACKGROUND OF THE INVENTION

1. Field of the Invention

The disclosure relates to a conversion device, and more particularly to an interface conversion device and a storage device using the interface conversion device.

2. Description of the Related Art

Generally speaking, a conventional mechanical turntable is still used inside the hard disk of serial attached small computer system interface (SCSI) (for short hereinafter referred as SAS) in the market. The hard disk which comprises the turntable is not vibration-proof, easy to get damage during transportation, heavy and noisy. Also, the hard disk consumes a large amount of electricity, and therefore requires enhanced heat dissipation and is relatively slow to boot.

However, common computer or server manufacturers still employ the conventional SAS hard disk having the turntable or a serial advanced technology attachment (for short hereinafter referred as SATA) hard disk for testing. The testing does not require a large amount of space for storing data so the unused space is a waste of resource. The testing time is also longer than that required for a solid state disk (SSD), thus the testing time is increased. Furthermore, a hard disk compatible for both SAS and SATA interfaces is not found in the market. Therefore, improvements can still be achieved for the two above-mentioned types of hard disks.

### SUMMARY OF THE INVENTION

An embodiment of the disclosure provides an interface conversion device applicable to a storage device. The interface conversion device comprises a first connection port, a second connection port, a measuring unit and a processing unit. The first connection port is configured to transmit a first signal and a power signal via a first communication interface. The second connection port is coupled to the storage device and is configured to transmit a second signal and the power signal via a second communication interface. The first communication interface and the second communication interface are different from each other. The measuring unit is coupled to the first connection port, the second connection port and the processing unit. The measuring unit is configured to receive the power signal from the first connection port in order to measure the power signal and to produce a measurement signal. The measuring unit is configured to output the power signal to the second connection port. The processing unit is coupled to the first connection port, the second connection port and the measuring unit. The processing unit is configured to receive the first signal from the first connection port, convert the first signal into the second signal and output the second signal via the second connection port. The processing unit is also configured to receive the measurement signal in order to calculate a power consumption value.

### BRIEF DESCRIPTION OF THE DRAWING

The disclosure will become more fully understood from the detailed description given herein below for illustration only, and thus are not limitative of the disclosure, and wherein:

The FIGURE is an illustration of a storage device of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Please refer to the FIGURE, which is an illustration of a storage device of the disclosure. A storage device 100 comprises a storage unit 110 and an interface conversion device 120. The storage unit 110, for example, is a solid state disk (SSD) used for storing and accessing data.

The interface conversion device 120 comprises a first connection port 130, a second connection port 140, a measuring unit 150 and a processing unit 160. The first connection port 130 is configured to transmit a first signal S1 and a power signal PS via a first communication interface. The first connection port 130, for example, is inserted onto a motherboard of an electronic device corresponding to the first communication interface such the first connection port 130 is configured to transmit data and electric power. The electronic device, for examples, is a server or a computer system.

The second connection port 140 is coupled to the storage unit 110 and is configured to transmit a second signal S2 and the power signal PS via a second communication interface. The second signal S2 is provided to the storage unit 110 such that the second signal S2 is adapted for performing corresponding data storing and accessing. The power signal PS is provided to the storage unit 110 as the electric power for the operation of the storage unit 110.

In this embodiment, the first communication interface and the second communication interface are different from each other. The first communication interface, for example, is a serial attached small computer system interface (for short hereinafter referred as SAS), e.g. SAS1.0, SAS2.0. The second communication interface, for example, is a serial advanced technology attachment interface (for short hereinafter referred as SATA), e.g. SATA3.0.

Furthermore, both the SAS2.0 interface and the SATA3.0 interface have a 6 GB/s signal transmission speed. In this embodiment, the first signal S1 is a signal having a SAS interface, and the second signal S2 is a signal having a SATA interface.

The measuring unit 150 is coupled to the first connection port 130 and the second connection port 140. The measuring unit 150 is configured to receive the power signal PS from the first connection port 130 in order to measure the power signal PS and to produce a measurement signal MS. In other words, the measuring unit 150 is configured to measure the power signal PS in order to obtain a voltage value and a current value of the power signal PS. Also, the measuring unit 150 is configured to output the measurement signal MS which is calculated from the obtained voltage value and the current value.

Furthermore, the measuring unit 150 further provides the power signal PS to the second connection port 140, the power signal PS may be transmitted to the storage unit 110 via the second connection port 140 to providing the electric power required.

The processing unit 160 is coupled to the first connection port 130, the second connection port 140 and the measuring unit 150. The processing unit 160 is configured to receive the first signal S1 from the first connection port 130, and convert the first signal S1 into the second signal S2. In other words, the processing unit 160 converts the first signal S1 having a SAS interface into the second signal S2 having a SATA interface in order to achieve the conversion of signal communication interface. Thus, the first signal S1 transmitted by the first connection port 130 is converted into the second signal S2 such that the first signal S1 may be transmitted through the second connection port 140. Then, the processing unit 160 outputs the second signal S2 to the storage unit 110 via the second connection port 140 for performing corresponding data storing and accessing.

In another embodiment, the processing unit 160 is adapted to receive the second signal S2 via the second connection port 140 and convert the second signal S2 into the first signal S1. In other words, the processing unit 160 converts the second signal S2 having a SATA interface into the first signal S1 having a SAS interface in order to achieve the conversion of signal communication interface. Thus, the second signal S2 transmitted by the second connection port 140 can be converted into the first signal S1 such that the second signal S2 may be transmitted through the first connection port 130. Then, the processing unit 160 outputs the first signal S1 to the electronic device via the first connection port 130 in order that the electronic device can read the data stored in the storage unit 110.

Additionally, the processing unit 160 is adapted to receive the measurement signal MS so as to calculate the power consumption value. In this embodiment, the processing unit 160 is coupled to the measuring unit 150, for example, via an inter-integrated circuit (I2C) bus for reading the voltage value and the current value of the measurement signal MS measured by the measuring unit 150 and calculating the corresponding power consumption value based on the changes of the voltage value and the current value.

Thereby, the interface conversion device 120 of this embodiment may not only perform conversion of communication interface, i.e. converting the SAS interface into the SATA interface and converting the SATA interface into the SAS interface, but also provide the power consumption data for users to know the operating status of the storage device 100 by reading the power consumption value calculated by the processing unit 160, thereby enhancing the convenience in usage.

To sum up, according to the interface conversion device and the storage device using the interface conversion device of the embodiments of the disclosure, the processing unit performs conversion of communication interface for the first signal of the first connection port transmitted via the first communication interface and the second signal of the second connection port transmitted via the second communication interface. Therefore, the first signal and the second signal may be transmitted via the corresponding communication interface. The measuring unit measures the power signals transmitted by the first connection port and the second connection port so as to produce the measurement signal for the processing unit to obtain the corresponding power consumption value based on the measurement signal. Therefore, not only the product compatibility is enhanced, but also data of the power consumption is provided for users to know the operating status of the storage device, and thus enhancing the convenience in usage.

1. An interface conversion device applicable to a storage device, the interface conversion device comprising:
a first connection port configured to transmit a first signal and a power signal via a first communication interface;
a second connection port coupled to the storage device and configured to transmit a second signal and the power signal via a second communication interface, wherein the first communication interface and the second communication interface are different from each other;
a measuring unit coupled to the first connection port and the second connection port, the measuring unit being configured to receive the power signal from the first connection port and measure the power signal in order to produce a measurement signal, and the measuring unit being configured to output the power signal to the second connection port; and
a processing unit coupled to the first connection port, the second connection port and the measuring unit, the processing being configured to receive the first signal from the first connection port and convert the first signal into the second signal in order to output the second signal via the second connection port, and the processing unit being configured to receive the measurement signal in order to calculate a power consumption value.

2. The interface conversion device as claimed in claim 1, wherein the first communication interface is a serial attached small computer system interface, and the second communication interface is a serial advanced technology attachment interface.

3. The interface conversion device as claimed in claim 1, wherein the measuring unit is coupled to the processing unit via an inter-integrated circuit bus.

4. A storage device, comprising:
a first connection port configured to transmit a first signal and a power signal via a first communication interface;
a second connection port configured to transmit a second signal and the power signal via a second communication interface;
a storage unit coupled to the second connection port and configured to receive the second signal and to perform an operation of storing and accessing;
a measuring unit coupled to the first connection port and the second connection port and configured to receive the power signal from the first connection port in order to measure the power signal and to produce a measurement signal, and the measuring unit being configured to output the power signal to the second connection port; and
a processing unit coupled to the first connection port, the second connection port and the measuring unit, the processing unit being configured to receive the first signal from the first connection port and convert the first signal into the second signal in order to output the second signal via the second connection port, and the processing unit being configured to receive the measurement signal in order to calculate a power consumption value.

5. The storage device as claimed in claim 4, wherein the first communication interface is a serial attached small computer system interface, and the second communication interface is a serial advanced technology attachment interface.

6. The storage device as claimed in claim 4, wherein the measuring unit is coupled to the processing unit via an inter-integrated circuit bus.

7. The storage device as claimed in claim 4, wherein the storage unit is a solid state disk.
